(19) United States
(12) Patent Application Publication
(10) Pub. No.: US 2017/0060470 A1
(43) Pub. Date: Mar. 2, 2017

(54) MEMORY SYSTEM AND OPERATING METHOD THEREOF

(71) Applicant: SK hynix Inc., Gyeonggi-do (KR)

(72) Inventor: Hoe-Seung JUNG, Gyeonggi-do (KR)

(21) Appl. No.: 15/009,384

(22) Filed: Jan. 28, 2016

(30) Foreign Application Priority Data
Aug. 31, 2015 (KR) 10-2015-0122568

(51) Int. Cl. G06F 3/06; G06F 13/42; G11C 16/10

(52) U.S. Cl. CPC G06F 3/0647; G11C 16/10; G06F 3/0604; G06F 3/0659; G06F 3/0679; G06F 13/4234

(57) ABSTRACT

A memory system may include: a memory device including: a plurality of pages each including a plurality of memory cells coupled to a plurality of word lines and suitable for storing read data and write data requested from a host; a plurality of memory blocks each including the pages; a plurality of planes each including the memory blocks; and a plurality of memory chips each including the planes; and a controller suitable for checking the write data corresponding to a command received from the host, programming the write data to pages of memory blocks included in planes of a first memory chip, and programming first data for the write data to pages of memory blocks included in planes of a second memory chip.

### CROSS-REFERENCE TO RELATED APPLICATIONS

This application claims priority under 35 U.S.C. §119 to Korean Patent Application No. 10-2015-0122568 filed on Aug. 31, 2015 with the Korean Intellectual Property Office, the disclosure of which is incorporated herein by reference in its entirety.

### BACKGROUND

1. Field

The present invention relates generally to a memory system, and more particularly, to a memory system which processes data to a memory device and an operating method thereof.

2. Description of the Related Art

The computer environment paradigm has shifted to ubiquitous computing systems that may be used anytime and anywhere. Due to this fact, the use of portable electronic devices such as mobile phones, digital cameras, and notebook computers has rapidly increased. Portable electronic devices generally employ a memory system having one or more semiconductor devices used main or auxiliary data storage devices.

Semiconductor memory devices generally provide excellent stability, durability, high information access speed, and low power consumption, since they have no moving parts. Well-known examples of semiconductor memory devices include universal serial bus (USB) memory devices, memory cards having various interfaces, and solid state drives (SSD).

### SUMMARY

Various embodiments are directed to a memory system capable of minimizing complexity and performance deterioration thereof, and rapidly and stably processing data to a memory device.

In an embodiment, a memory system may include: a plurality of memory chips each memory chip comprising a plurality of planes, each plane comprising a plurality of memory blocks, each block comprising a plurality of pages; the plurality of pages being suitable for storing read data and write data requested from a host, each page comprising a plurality of memory cells coupled to a plurality of word lines; and a controller suitable for checking the write data corresponding to a command received from the host, programming the write data to pages of memory blocks included in planes of a first memory chip, and programming first data for the write data to pages of memory blocks included in planes of a second memory chip.

The first data may include backup data of the write data.

The first data may include data programmed to the LSB (Least Significant Bit) page among the pages of the memory blocks included in the planes of the first memory chip.

The first data may include data having the same pattern as the write data.

The first data may include the same data as data programmed to the MSB (Most Significant Bit) page among the pages of the memory blocks included in the planes of the first memory chip and data programmed to the MSB page among the pages of the memory blocks included in the planes of the second memory chip.

The first and second memory chips may be coupled to the same channel and share a data bus.

The controller may enable the first and second memory chips through the shared data bus of the first and second memory chips, and transmit the write data to the first and second memory chips through the shared data bus at the same time.

The controller may generate one descriptor for the data programmed to the first and second memory chips, and then transmit a command containing the descriptor to the first and second memory chips through the shared data bus at the same time.

The controller may check the write data and information type of the write data and program the write data to multi-memory chips among the memory chips at the same time.

The controller may program the write data to pages of a first memory block included in a first plane of the first memory chip, and then program the first data to pages of a memory block included in a second plane of the first memory chip or pages of a second memory block included in the first plane.

In an embodiment, an operating method of a memory system may include: checking write data corresponding to a command received from a host, for a plurality of pages included in each of a plurality of memory blocks of a memory device and each including a plurality of memory cells coupled to a plurality of word lines; enabling first and second memory chips among a plurality of memory chips included in the memory device; and programming the write data to pages of memory blocks included in planes of the first memory chip, and programming first data for the write data to pages of memory blocks included in planes of the second memory chip.

The first data may include backup data of the write data.

The first data may include data programmed to the LSB page among the pages of the memory blocks included in the planes of the first memory chip.

The first data may include data having the same pattern as the write data.

The first data may include the same data as data programmed to the MSB page among the pages of the memory blocks included in the planes of the first memory chip and data programmed to the MSB page among the pages of the memory blocks included in the planes of the second memory chip.

The first and second memory chips may be coupled to the same channel and share a data bus.

The enabling of the first and second memory chips may include enabling the first and second memory chips through the shared data bus of the first and second memory chips, and the programming of the write data may include transmitting the write data to the first and second memory chips through the shared data bus at the same time.

The transmitting of the write data may include: generating one descriptor for the data programmed to the first and second memory chips; and transmitting a command containing the descriptor to the first and second memory chips through the shared data bus at the same time.

The checking of the write data may include checking the write data and information type of the write data, and checking whether the write data are programmed to multi-memory chips among the memory chips at the same time.

The programming of the write data may include programming the write data to pages of a first memory block included in a first plane of the first memory chip, and then programming the first data to pages of a memory block included in a second plane of the first memory chip or pages of a second memory block included in the first plane.

### BRIEF DESCRIPTION OF THE DRAWINGS

FIG. 1 is a diagram illustrating a data processing system including a memory system, according to an embodiment of the present invention.

FIG. 2 is a diagram illustrating an example of a memory device employed in the memory system of FIG. 1.

FIG. 3 is a circuit diagram illustrating an example of a memory block employed in a memory device, according to an embodiment of the present invention.

FIGS. 4 to 11 are diagrams schematically illustrating examples of a memory device, according to an embodiment of the present invention.

FIGS. 12 and 13 are diagrams illustrating an example of an operation of processing data, according to an embodiment of the present invention.

FIG. 14 is a flowchart illustrating an example of an operation of processing data, according to an embodiment of the present invention.

### DETAILED DESCRIPTION

Various embodiments of the present invention will be described below in more detail with reference to the accompanying drawings. The present invention may, however, be embodied in different forms and should not be construed as being limited to the embodiments set forth herein. Rather, these embodiments are provided so that this disclosure will be thorough and complete. Throughout the disclosure, like reference numerals refer to like parts throughout the various figures and embodiments of the present invention.

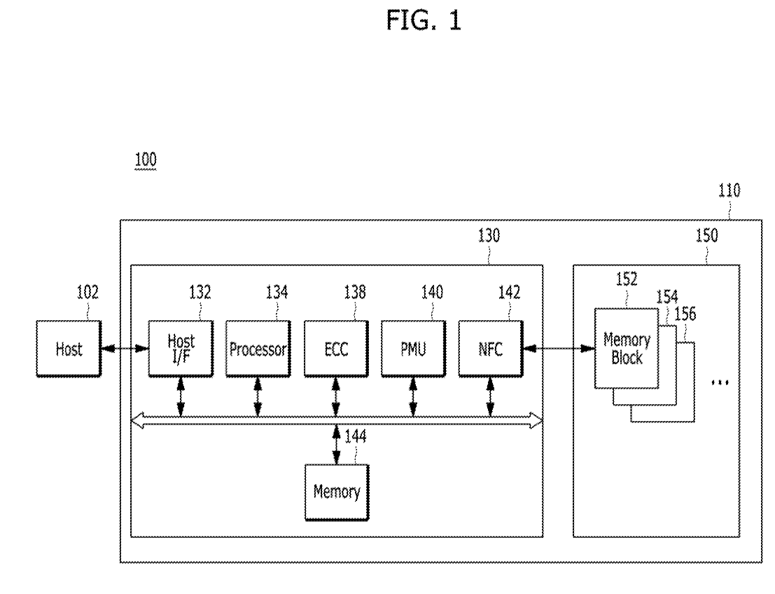

Referring now to FIG. 1, a data processing system 100, according to an embodiment of the present invention may include a host 102 and a memory system 110.

The host 102 may include, for example, a portable electronic device such as a mobile phone, an MP3 player and a laptop computer, or a non-potable electronic device such as a desktop computer, a game player, a TV, a projector and the like.

The memory system 110 may store data to be accessed by the host 102 in response to a request from the host 102. For example, the memory system 110 may be used as a main memory system or an auxiliary memory system of the host 102. The memory system 110 may be to be electrically coupled with the host 102, according to a protocol of a host interface.

The memory system 110 may be implemented with any one of various kinds of storage devices such as a solid state drive (SSD), a multimedia card (MMC), an embedded MMC (eMMC), a reduced size MMC (RS-MMC) and a micro-MMC, a secure digital (SD) card, a mini-SD and a micro-SD, a universal serial bus (USB) storage device, a universal flash storage (UFS) device, a compact flash (CF) card, a smart media (SM) card, a memory stick, and the like.

The storage devices for the memory system 110 may be implemented with a volatile memory device such as a dynamic random access memory (DRAM), a static random access memory (SRAM) and the like. Alternatively, the storage devices for the memory system 110 may be implemented with a nonvolatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), a resistive RAM (RRAM) and the like.

The memory system 110 may include a memory device 150 for storing data, and a controller 130 for controlling the storage of data in the memory device 150. The stored data in the memory device 150 may be accessed by the host 102.

The controller 130 and the memory device 150 may be integrated into a semiconductor device. For instance, the controller 130 and the memory device 150 may be integrated into a semiconductor device configured as a solid state drive (SSD). When the memory system 110 is used as a SSD, the operation speed of the host 102 that is electrically coupled with the memory system 110 may be substantially increased.

The controller 130 and the memory device 150 may be integrated into a semiconductor device configured as a memory card such as a Personal Computer Memory Card International Association (PCMCIA) card, a compact flash (CF) card, a smart media (SM) card (SMC), a memory stick, a multimedia card (MMC), an RS-MMC and a micro-MMC, a secure digital (SD) card, a mini-SD, a micro-SD and an SDHC, a universal flash storage (UFS) device and the like.

For another instance, the memory system 110 may configure a computer, an ultra-mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation device, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a storage configuring a data center, a device capable of transmitting and receiving information under a wireless environment, one of various electronic devices configuring a home network, one of various electronic devices configuring a computer network, one of various electronic devices configuring a telematics network, an RFID device, one of various component elements configuring a computing system and the like.

The memory device 150 may retain stored data when a power supply is interrupted. During a write operation, the memory device 150 may store data provided from the host 102. During a read operation, the memory device 150 may provide stored data to the host 102. One or more memory devices like the memory device 150 may be employed.

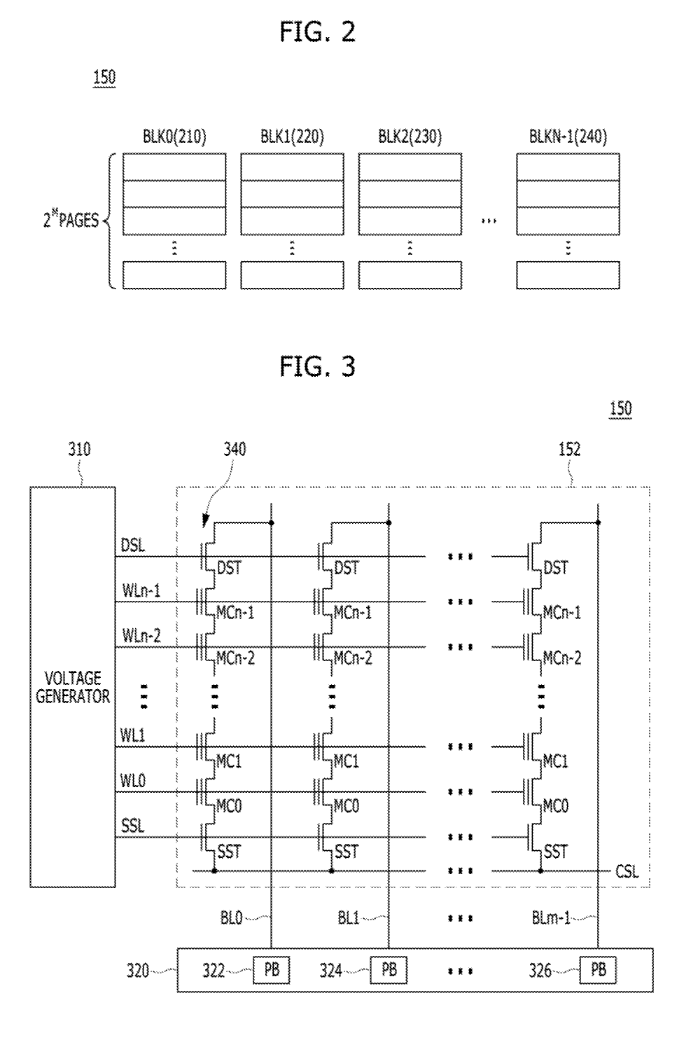

The memory device 150 may include a plurality of memory blocks 152, 154 and 156. Each of the memory blocks 152, 154 and 156 may include a plurality of pages. Each of the pages may include a plurality of memory cells which may be electrically coupled to a plurality of word lines (WL). The memory device 150 may be a nonvolatile memory device, for example, a flash memory. The memory device 150 may have a three-dimensional (3D) stack structure. In an embodiment, the memory device may be a flash memory having a 3D stack structure. The structure of the memory device 150 including a three-dimensional (3D) stack structure will be described later in detail with reference to FIGS. 2 to 11.

The controller 130 may control the overall operations of the memory device 150, such as read, write, program and erase operations. The controller 130 may control the memory device 150 in response to a request from the host 102. For example, the controller 130 may provide data read from the memory device 150 to the host 102 in response to a read request from the host 102. Or, also as an example, the controller may store data provided from the host 102 into the memory device 150 in response to a write request.

In an embodiment, the controller 130 may include a host interface unit 132, a processor 134, an error correction code (ECC) unit 138, a power management unit (PMU) 140, a NAND flash controller (NFC) 142, and a memory 144.

The host interface unit 132 may process commands and data provided from the host 102. The host interface unit 132 may communicate with the host 102 through at least one of various interface protocols such as a universal serial bus (USB), a multimedia card (MMC), a peripheral component interconnect-express (PCI-E), a serial attached SCSI (SAS), a serial advanced technology attachment (SATA), a parallel advanced technology attachment (PATA), a small computer system interface (SCSI), an enhanced small disk interface (ESDI), an integrated drive electronics (IDE) and the like.

The ECC unit 138 may detect and correct errors of the data read from the memory device 150 during a read operation. In an embodiment, if the number of error bits detected by the ECC unit 138 is greater than or equal to a threshold number of correctable error bits, the ECC unit 138 may not correct the error bits but output an error correction fail signal indicating failure in correcting the error bits.

The ECC unit 138 may perform an error correction operation based on any suitable error correction scheme. For example, the ECC unit 138 may perform an error correction operation based on a coded modulation scheme such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), and the like. The ECC unit 138 may include any suitable circuits, systems or devices for the error correction operation.

The PMU 140 may provide and manage electric power for the controller 130, for example, power for the various components of the controller 130. The PMU 140 may provide different voltage power to the various components of the controller as may be needed. The PMU 140 may provide same voltage power to the various components of the controller.

The NFC 142 may serve as a memory interface between the controller 130 and the memory device 150 to allow the controller 130 to control the memory device 150 in response to a request from the host 102. For example, the NFC 142 may generate control signals for the memory device 150 and process data under the control of the processor 134 when the memory device 150 is a flash memory, especially a NAND flash memory.

The memory 144 may serve as a working memory of the memory system 110 and the controller 130, and store data for driving the memory system 110 and the controller 130. For example, when the controller 130 controls the operations of the memory device 150, the memory 144 may store data used by the controller 130 and the memory device 150 for such operations as read, write, program and erase operations.

The memory 144 may be or comprise a volatile memory. For example, the memory 144 may be or comprise a static random access memory (SRAM) or a dynamic random access memory (DRAM). As described above, the memory 144 may store data used by the host 102 and the memory device 150 for read and/or write operations. The memory 144 may be or comprise a program memory, a data memory, a write buffer, a read buffer, a map buffer, and the like.

The processor 134 may control the general operations of the memory system 110. The processor 134 may control a write or a read operation for the memory device 150, in response to a write or read request from the host 102. The processor 134 may drive a firmware, also referred to as a flash translation layer (FTL), for controlling the general operations of the memory system 110. The processor 134 may be implemented with a microprocessor, a central processing unit (CPU) and the like.

A management unit (not shown) may be included in the processor 134 for performing a bad block management of the memory device 150. For example, the management unit may find bad memory blocks included in the memory device 150, i.e., memory blocks which are in an unsatisfactory condition for further use, and perform a bad block management on the bad memory blocks. When a flash memory, for example, a NAND flash memory is employed as the memory device 150, a program failure may occur during the write operation, for example, during the program operation, due to inherent characteristics of a NAND logic function. During a bad block management, the data of the program-failed memory blocks or the bad memory blocks may be programmed into a new memory block. Also, the bad blocks due to the program fail may seriously deteriorate the utilization efficiency of the memory device 150 having a 3D stack structure and the reliability of the memory system 100, and thus reliable bad block management is required.

Referring to FIG. 2, the memory device 150 may include a plurality of memory blocks, for example, zeroth to (N−1)^{th} blocks 210 to 240, where N is a positive integer. Each of the plurality of memory blocks 210 to 240 may include a plurality of pages, for example, 2^{M} number of pages (2^{M} PAGES), where M is a positive integer. Each of the plurality of pages may include a plurality of memory cells to which a plurality of word lines are electrically coupled. It is noted that any number of suitable blocks and pages per block may be employed.

The memory blocks may be single level cell (SLC) memory blocks and/or multi-level cell (MLC) memory blocks, according to the number of bits which may be stored or expressed in each memory cell. An SLC memory block may include a plurality of pages which are implemented with memory cells each capable of storing 1-bit data. An MLC memory block may include a plurality of pages which are implemented with memory cells each capable of storing multi-bit data, for example, two or more-bit data. An MLC memory block including a plurality of pages which are implemented with memory cells each capable of storing 3-bit data may also be referred to as a triple level cell (TLC) memory block.

Each of the plurality of memory blocks 210 to 240 may store data provided from the host device 102 during a write operation, and may provide stored data to the host 102 during a read operation.

FIG. 3 is a circuit diagram illustrating one of the plurality of memory blocks 152 to 156, according to an embodiment of the present invention.

Referring to FIG. 3, the memory block 152 of the memory device 150 may include a plurality of cell strings 340 which are electrically coupled to bit lines BL0 to BLm−1, respectively. Each cell string 340 may include at least one drain select transistor DST and at least one source select transistor SST. A plurality of memory cells or a plurality of memory cell transistors MC0 to MCn−1 may be electrically coupled in series between the select transistors DST and SST. The respective memory cells MC0 to MCn−1 may consist of multi-level cells (MLC), each of which stores data information of a plurality of bits. The memory cells may have any suitable architecture.

In FIG. 3, ‘DSL’ denotes a drain select line, ‘SSL’ denotes a source select line, and ‘CSL’ denotes a common source line.

FIG. 3 shows, as an example, a memory block 152 configured by NAND flash memory cells. It is noted, however, that the memory block 152 of the memory device 150 according to the embodiment is not limited to NAND flash memory and may be realized by NOR flash memory, hybrid flash memory having at least two kinds of memory cells are combined, or one-NAND flash memory having a controller is built in a memory chip. The operational characteristics of a semiconductor device may be applied to not only a flash memory device in which a charge storing layer consists of conductive floating gates but also a charge trap flash (CTF) in which a charge storing layer consists of a dielectric layer.

It is also noted that the memory device 150 is not limited to a flash memory device only. For example, the memory device 150 may be a DRAM or a SRAM device.

A voltage generator 310 of the memory device 150 may generate word line voltages, for example, a program voltage, a read voltage and a pass voltage, to supply to respective word lines according to an operation mode. Further, the voltage generator 310 may generate voltages to be supplied to bulks, for example, well regions in which the memory cells are formed. The voltage generator 310 may perform a voltage generating operation under a control of a control circuit (not shown). The voltage generator 310 may generate a plurality of variable read voltages to generate a plurality of read data. The voltage generator 310 may select one of the memory blocks or sectors of a memory cell array, select one of the word lines of the selected memory block, and provide the word line voltages to the selected word line and unselected word lines, under the control of the control circuit.

A read/write circuit 320 of the memory device 150 may be controlled by the control circuit, and may serve as a sense amplifier or a write driver according to an operation mode. During a verification/normal read operation, the read/write circuit 320 may serve as a sense amplifier for reading data from the memory cell array. Also, during a program operation, the read/write circuit 320 may serve as a write driver for driving bit lines according to data to be stored in the memory cell array. The read/write circuit 320 may receive data to be written in the memory cell array, from a buffer (not shown), during the program operation, and may drive the bit lines according to the inputted data. To this end, the read/write circuit 320 may include a plurality of page buffers 322, 324 and 326 respectively corresponding to the columns (or bit lines) or pairs of the columns (or pairs of bit lines). Each of the page buffers 322, 324 and 326 may include a plurality of latches (not shown).

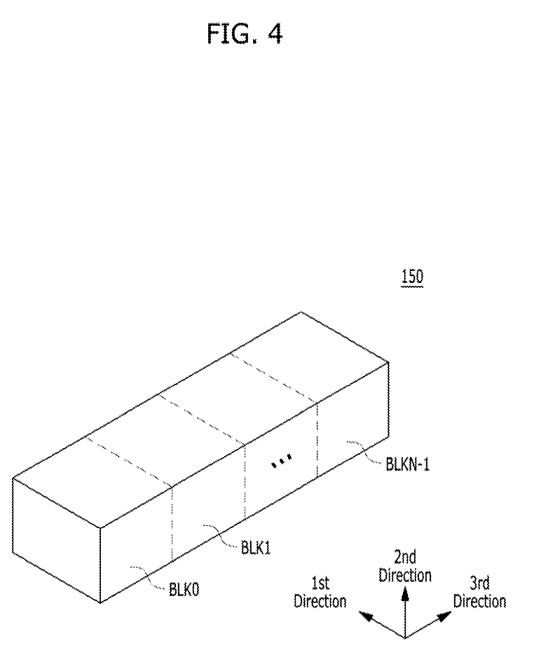

FIG. 4 is a block diagram illustrating an example of the plurality of memory blocks 152 to 156 of the memory device 150 according to an embodiment of the present invention.

Referring to FIG. 4, the memory device 150 may include a plurality of memory blocks BLK0 to BLKN−1. Each of the memory blocks BLK0 to BLKN−1 may be realized in a three-dimensional (3D) structure or a vertical structure. The respective memory blocks BLK0 to BLKN−1 may include a plurality of structures extending in first to third directions, for example, an x-axis direction, a y-axis direction and a z-axis direction.

The respective memory blocks BLK0 to BLKN−1 may include a plurality of NAND strings NS extending in the second direction. The plurality of NAND strings NS may be provided in the first direction and the third direction. Each NAND string NS may be electrically coupled to a bit line BL, at least one source select line SSL, at least one ground select line GSL, a plurality of word lines WL, at least one dummy word line DWL, and a common source line CSL. For example, the respective memory blocks BLK0 to BLKN−1 may be electrically coupled to a plurality of bit lines BL, a plurality of source select lines SSL, a plurality of ground select lines GSL, a plurality of word lines WL, a plurality of dummy word lines DWL, and a plurality of common source lines CSL.

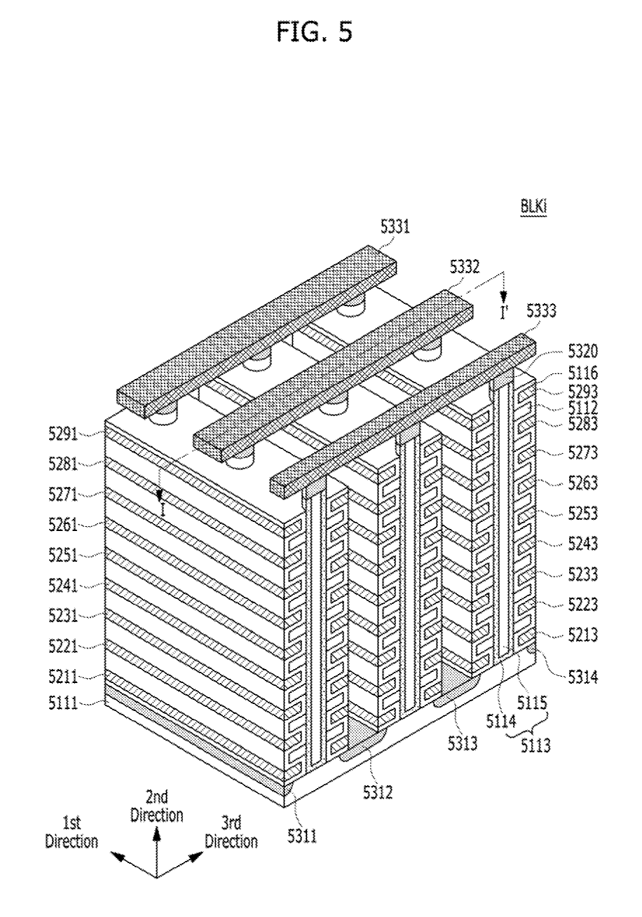

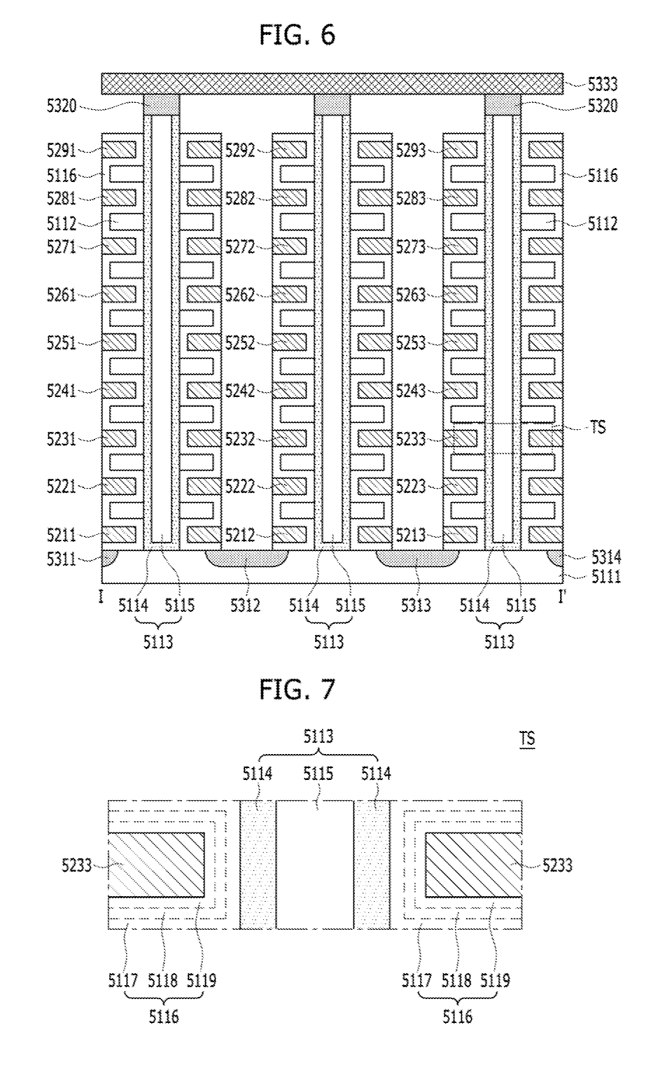

FIG. 5 is a perspective view of one BLKi of the plurality of memory blocks BLK0 to BLKN−1 shown in FIG. 4. FIG. 6 is a cross-sectional view taken along a line I-I′ of the memory block BLKi shown in FIG. 5.

Referring to FIGS. 5 and 6, a memory block BLKi among the plurality of memory blocks of the memory device 150 may include a structure extending in the first to third directions.

A substrate 5111 may be provided. The substrate 5111 may include a silicon material doped with a first type impurity. The substrate 5111 may include a silicon material doped with a p-type impurity. The substrate 511 may be a p-type well, for example, a pocket p-well. The substrate 511 may further include an n-type well surrounding the p-type well. Although, in the embodiment of the present invention, the substrate 5111 is exemplified as being the p-type silicon, it is noted that the substrate 5111 is not limited to the p-type silicon.

A plurality of doping regions 5311 to 5314 extending in the first direction may be provided over the substrate 5111. The plurality of doping regions 5311 to 5314 may contain a second type impurity that is different from that of the substrate 5111. The plurality of doping regions 5311 to 5314 may be doped with an n-type impurity. Although, in the embodiment of the present invention, first to fourth doping regions 5311 to 5314 are exemplified as being the n-type, it is noted that they are not limited to the n-type.

In the region over the substrate 5111 between the first and second doping regions 5311 and 5312, a plurality of dielectric materials 5112 extending in the first direction may be sequentially provided in the second direction. The dielectric materials 5112 may be separated from the substrate 5111 by a preset distance in the second direction. Each of dielectric materials 5112 may be separated from one another by a preset distance in the second direction. The dielectric materials 5112 may include a dielectric material such as silicon oxide.

In the region over the substrate 5111 between the first and second doping regions 5311 and 5312, a plurality of pillars 5113 which are sequentially disposed in the first direction and pass through the dielectric materials 5112 in the second direction may be provided. The plurality of pillars 5113 may respectively pass through the dielectric materials 5112 and may be electrically coupled with the substrate 5111. Each pillar 5113 may be configured by a plurality of materials. A surface layer 5114 of each pillar 5113 may include a silicon material doped with the first type of impurity. The surface layer 5114 of each pillar 5113 may include a silicon material doped with the same type of impurity as the substrate 5111. Although, in the embodiment of the present invention, the surface layer 5114 of each pillar 5113 is exemplified as including p-type silicon, the surface layer 5114 of each pillar 5113 is not limited to the p-type silicon.

An inner layer 5115 of each pillar 5113 may be formed of a dielectric material. The inner layer 5115 of each pillar 5113 may be filled by a dielectric material such as silicon oxide.

In the region between the first and second doping regions 5311 and 5312, a dielectric layer 5116 may be provided along exposed surfaces of the dielectric materials 5112, the pillars 5113 and the substrate 5111. A thickness of the dielectric layer 5116 may be less than one half of the distance between the dielectric materials 5112. In other words, a region of a material other than the dielectric material 5112 and the dielectric layer 5116 may be provided between (i) the dielectric layer 5116 provided below the bottom surface of a first dielectric material of the dielectric materials 5112 and (ii) the dielectric layer 5116 provided over the top surface of a second dielectric material of the dielectric materials 5112. The dielectric materials 5112 may lie below the first dielectric material.

In the region between the first and second doping regions 5311 and 5312, conductive materials 5211 to 5291 may be provided over an exposed surface of the dielectric layer 5116. The conductive material 5211 extending in the first direction may be provided between the dielectric material 5112 adjacent to the substrate 5111 and the substrate 5111. In particular, the conductive material 5211 extending in the first direction may be provided between (i) the dielectric layer 5116 disposed over the substrate 5111 and (ii) the dielectric layer 5116 disposed below the bottom surface of the dielectric material 5112 adjacent to the substrate 5111.

The conductive material extending in the first direction may be provided between (i) the dielectric layer 5116 disposed over the top surface of one of the dielectric materials 5112 and (ii) the dielectric layer 5116 disposed below the bottom surface of another dielectric material of the dielectric materials 5112, which is disposed over the one dielectric material 5112. The conductive materials 5221 to 5281 extending in the first direction may be provided between the dielectric materials 5112. The top conductive material 5291 extending in the first direction may be provided over the uppermost dielectric material 5112. The conductive materials 5211 to 5291 extending in the first direction may be made of a metallic material. The conductive materials 5211 to 5291 extending in the first direction may be made of a conductive material such as polysilicon.

In the region between the second doping region 5312 and a third doping region 5313, the same structures as the structures between the first and second doping regions 5311 and 5312 may be provided. For example, in the region between the second and third doping regions 5312 and 5313, the plurality of dielectric materials 5112 extending in the first direction, the plurality of pillars 5113 which are sequentially arranged in the first direction and pass through the plurality of dielectric materials 5112 in the second direction, the dielectric layer 5116 which is provided over the exposed surfaces of the plurality of dielectric materials 5112 and the plurality of pillars 5113, and the plurality of conductive materials 5212 to 5292 extending in the first direction may be provided.

In the region between the third doping region 5313 and a fourth doping region 5314, the same structures as between the first and second doping regions 5311 and 5312 may be provided. For example, in the region between the third and fourth doping regions 5313 and 5314, the plurality of dielectric materials 5112 extending in the first direction, the plurality of pillars 5113 which are sequentially arranged in the first direction and pass through the plurality of dielectric materials 5112 in the second direction, the dielectric layer 5116 which is provided over the exposed surfaces of the plurality of dielectric materials 5112 and the plurality of pillars 5113, and the plurality of conductive materials 5213 to 5293 extending in the first direction may be provided.

Drains 5320 may be respectively provided over the plurality of pillars 5113. The drains 5320 may be made of silicon materials doped with second type impurities. The drains 5320 may be made of silicon materials doped with n-type impurities. Although, for the sake of convenience of explanation, the drains 5320 are exemplified as including n-type silicon, it is noted that the drains 5320 are not limited to the n-type silicon. For example, the width of each drain 5320 may be larger than the width of each corresponding pillar 5113. Each drain 5320 may be provided in the shape of a pad over the top surface of each corresponding pillar 5113.

Conductive materials 5331 to 5333 extending in the third direction may be provided over the drains 5320. Each of the conductive materials 5331 to 5333 may be extendedly disposed over the drains 5320 serially arranged in the third direction with a preset separation distance to each other in the first direction. The respective conductive materials 5331 to 5333 may be electrically coupled with the drains 5320 therebelow. The drains 5320 and the conductive materials 5331 to 5333 extending in the third direction may be electrically coupled with through contact plugs. The conductive materials 5331 to 5333 extending in the third direction may be made of a metallic material. The conductive materials 5331 to 5333 extending in the third direction may be made of a conductive material such as polysilicon.

In FIGS. 5 and 6, the respective pillars 5113 may form strings together with the dielectric layer 5116 and the conductive materials 5211 to 5291, 5212 to 5292 and 5213 to 5293 extending in the first direction. The respective pillars 5113 may form NAND strings NS together with the dielectric layer 5116 and the conductive materials 5211 to 5291, 5212 to 5292 and 5213 to 5293 extending in the first direction. Each NAND string NS may include a plurality of transistor structures TS.

Referring now to FIG. 7, in the transistor structure TS shown in FIG. 6, the dielectric layer 5116 may include first to third sub dielectric layers 5117, 5118 and 5119.

The surface layer 5114 of p-type silicon in each of the pillars 5113 may serve as a body. The first sub dielectric layer 5117 adjacent to the pillar 5113 may serve as a tunneling dielectric layer, and may include a thermal oxidation layer.

The second sub dielectric layer 5118 may serve as a charge storing layer. The second sub dielectric layer 5118 may serve as a charge capturing layer, and may include a nitride layer or a metal oxide layer such as an aluminum oxide layer, a hafnium oxide layer, or the like.

The third sub dielectric layer 5119 adjacent to the conductive material 5233 may serve as a blocking dielectric layer. The third sub dielectric layer 5119 adjacent to the conductive material 5233 extending in the first direction may be formed as a single layer or multiple layers. The third sub dielectric layer 5119 may be a high-k dielectric layer such as an aluminum oxide layer, a hafnium oxide layer, or the like, which has a dielectric constant greater than the first and second sub dielectric layers 5117 and 5118.

The conductive material 5233 may serve as a gate or a control gate. For example, the gate or the control gate 5233, the blocking dielectric layer 5119, the charge storing layer 5118, the tunneling dielectric layer 5117 and the body 5114 may form a transistor or a memory cell transistor structure. For example, the first to third sub dielectric layers 5117 to 5119 may form an oxide-nitride-oxide (ONO) structure. In the embodiment, for the sake of convenience of explanation, the surface layer 5114 of p-type silicon in each of the pillars 5113 will be referred to as a body in the second direction.

The memory block BLKi may include the plurality of pillars 5113. For example, the memory block BLKi may include the plurality of NAND strings NS. In detail, the memory block BLKi may include the plurality of NAND strings NS extending in the second direction or a direction perpendicular to the substrate 5111.

Each NAND string NS may include the plurality of transistor structures TS which are disposed in the second direction. At least one of the plurality of transistor structures TS of each NAND string NS may serve as a string source transistor SST. At least one of the plurality of transistor structures TS of each NAND string NS may serve as a ground select transistor GST.

The gates or control gates may correspond to the conductive materials 5211 to 5291, 5212 to 5292 and 5213 to 5293 extending in the first direction. For example, the gates or the control gates may extend in, the first direction and form word lines and at least two select lines including at least one source select line SSL and at least one ground select line GSL.

The conductive materials 5331 to 5333 extending in the third direction may be electrically coupled to one ends of the NAND strings NS. The conductive materials 5331 to 5333 extending in the third direction may serve as bit lines BL. For example, in one memory block BLKi, the plurality of NAND strings NS may be electrically coupled to one bit line BL.

The second type doping regions 5311 to 5314 extending in the first direction may be provided to the other ends of the NAND strings NS. The second type doping regions 5311 to 5314 extending in the first direction may serve as common source lines CSL.

For example, the memory block BLKi may include a plurality of NAND strings NS extending in a direction perpendicular to the substrate 5111, e.g., the second direction, and may serve as a NAND flash memory block, for example, of a charge capturing type memory, in which the plurality of NAND strings NS are electrically coupled to one bit line BL.

Although it is illustrated in FIGS. 5 to 7 that the conductive materials 5211 to 5291, 5212 to 5292 and 5213 to 5293 extending in the first direction are provided by nine (9) layers, it is noted that the conductive materials 5211 to 5291, 5212 to 5292 and 5213 to 5293 extending in the first direction are not limited thereto. For example, conductive materials extending in the first direction may be provided in eight (8) layers, sixteen (16) layers or any multiple layers. For example, in one NAND string NS, the number of transistors may be 8, 16 or more.

Although it is illustrated in FIGS. 5 to 7 that three (3) NAND strings NS are electrically coupled to one bit line BL, it is noted that the embodiment is not limited thereto. In the memory block BLKi, m NAND strings NS may be electrically coupled to one bit line BL, m being a positive integer. The number of conductive materials 5211 to 5291, 5212 to 5292 and 5213 to 5293 extending in the first direction and the number of common source lines 5311 to 5314 may vary with the number of NAND strings NS which are electrically coupled to one bit line BL.

Further, although it is illustrated in FIGS. 5 to 7 that three (3) NAND strings NS are electrically coupled to one conductive material extending in the first direction, it is noted that the embodiment is not limited thereto. For example, n NAND strings NS may be electrically coupled to one conductive material extending in the first direction, n being a positive integer. The number of bit lines 5331 to 5333 may vary with the number of NAND strings NS which are electrically coupled to one conductive material extending in the first direction.

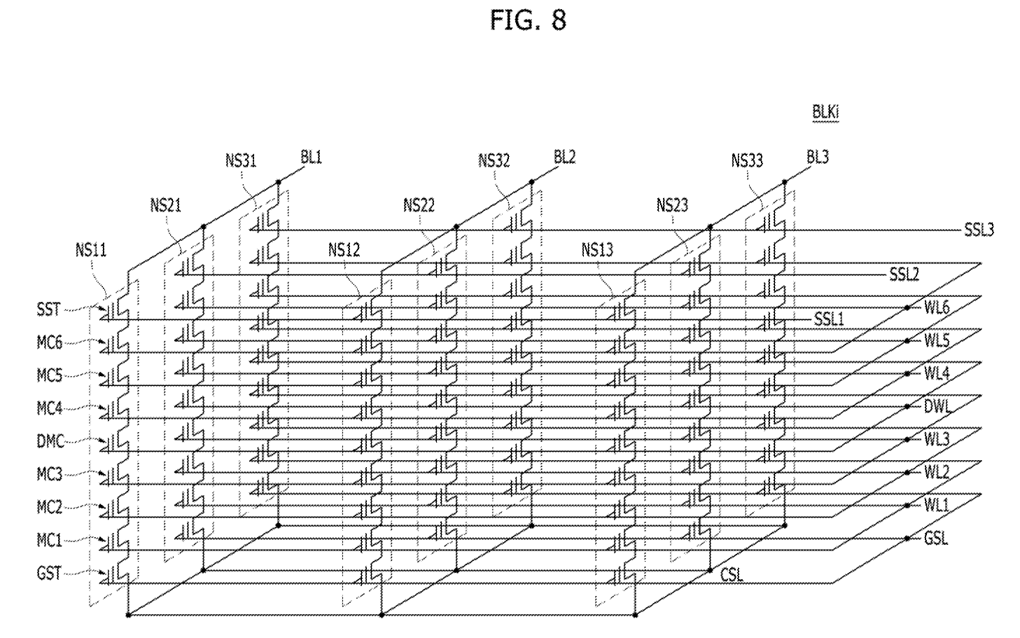

Referring to FIG. 8, in a block BLKi having the first structure, NAND strings NS11 to NS31 may be provided between a first bit line BL1 and a common source line CSL. The first bit line BL1 may correspond to the conductive material 5331 of FIGS. 5 and 6, extending in the third direction. NAND strings NS12 to NS32 may be provided between a second bit line 8L2 and the common source line CSL. The second bit line BL2 may correspond to the conductive material 5332 of FIGS. 5 and 6, extending in the third direction. NAND strings NS13 to NS33 may be provided between a third bit line BL3 and the common source line CSL. The third bit line BL3 may correspond to the conductive material 5333 of FIGS. 5 and 6, extending in the third direction.

A source select transistor SST of each NAND string NS may be electrically coupled to a corresponding bit line BL. A ground select transistor GST of each NAND string NS may be electrically coupled to the common source line CSL. Memory cells MC1 to MC6 may be provided between the source select transistor SST and the ground select transistor GST of each NAND string NS.

In this example, the NAND strings NS may be defined by units of rows and columns. The NAND strings NS which are electrically coupled to one bit line may form one column. The NAND strings NS11 to NS31 which are electrically coupled to the first bit line BL1 may correspond to a first column. The NAND strings NS12 to NS32 which are electrically coupled to the second bit line BL2 may correspond to a second column. The NAND strings NS13 to NS33 which are electrically coupled to the third bit line BL3 may correspond to a third column. The NAND strings NS which are electrically coupled to one source select line SSL may form one row. The NAND strings NS11 to NS13 which are electrically coupled to a first source select line SSL1 may form a first row. The NAND strings NS21 to NS23 which are electrically coupled to a second source select line SSL2 may form a second row. The NAND strings NS31 to NS33 which are electrically coupled to a third source select line SSL3 may form a third row.

In each NAND string NS, a height may be defined. In each NAND string NS, the height of the memory cell MC1 adjacent to the ground select transistor GST may have, for example, a value ‘1’. In each NAND string NS, the height of a memory cell may increase as the memory cell gets closer to the source select transistor SST when measured from the substrate 5111. In each NAND string NS, the height of a memory cell MC6 adjacent to the source select transistor SST may have, for example, a value ‘7’.

The source select transistors SST of the NAND strings NS arranged in the same row may share the source select line SSL. The source select transistors SST of the NAND strings NS arranged in different rows may be respectively electrically coupled to the different source select lines SSL1, SSL2 and SSL3.

The memory cells at the same height in the NAND strings NS in the same row may share a word line WL. For example, at the same height, the word lines WL electrically coupled to the memory cells MC of the NAND strings NS in different rows may be electrically coupled with each other. Dummy memory cells DMC at the same height in the NAND strings NS of the same row may share a dummy word line DWL. For example, at the same height or level, the dummy word lines DWL electrically coupled to the dummy memory cells DMC of the NAND strings NS in different rows may be electrically coupled with each other.

The word lines WL or the dummy word lines DWL located at the same level or height or layer may be electrically coupled with each other for each of layers where the conductive materials 5211 to 5291, 5212 to 5292 and 5213 to 5293 extending in the first direction may be provided. The conductive materials 5211 to 5291, 5212 to 5292 and 5213 to 5293 extending in the first direction may be electrically coupled in common to upper layers through contacts. In other words, the ground select transistors GST of the NAND strings NS in the same row may share the ground select line GSL Further, the ground select transistors GST of the NAND strings NS in different rows may share the ground select line GSL. For example, the NAND strings NS11 to NS13, NS21 to NS23 and NS31 to NS33 may be electrically coupled in common to the ground select line GSL

The common source line CSL may be electrically coupled in common to the NAND strings NS. Over the active regions over the substrate 5111, the first to fourth doping regions 5311 to 5314 may be electrically coupled. The first to fourth doping regions 5311 to 5314 may be electrically coupled in common to an upper layer through contacts.

For example, as shown in FIG. 8, the word lines WL of the same height or level may be electrically coupled to each other. Accordingly, when a word line WL at a certain height is selected, all NAND strings NS which are electrically coupled to the selected word line WL may be selected. The NAND strings NS in different rows may be electrically coupled to different source select lines SSL. Accordingly, among the NAND strings NS electrically coupled to the same word line WL, by selecting one of the source select lines SSL1 to SSL3, the NAND strings NS in the unselected rows may be electrically isolated from the bit lines BL1 to BL3. In other words, by selecting one of the source select lines SSL1 to SSL3, the NAND strings NS arranged in the same row as the selected source line may be selected. Furthermore, by selecting one of the bit lines BL1 to BL3, the NAND strings NS arranged in the same column as the selected bit line may be selected. Accordingly, only the NAND strings NS arranged in the same row as the selected source line and the same column as the selected bit line may be selected.

In each NAND string NS, a dummy memory cell DMC may be provided. In FIG. 8, for example, the dummy memory cell DMC may be provided between a third memory cell MC3 and a fourth memory cell MC4 in each NAND string NS. For example, first to third memory cells MC1 to MC3 may be provided between the dummy memory cell DMC and the ground select transistor GST. Fourth to sixth memory cells MC4 to MC6 may be provided between the dummy memory cell DMC and the source select transistor SST. The memory cells MC of each NAND string NS may be divided into two (2) memory cell groups by the dummy memory cell DMC. In the divided memory cell groups, memory cells, for example, MC1 to MC3, adjacent to the ground select transistor GST may be referred to as a lower memory cell group, and remaining memory cells, for example, MC4 to MC6, adjacent to the string select transistor SST may be referred to as an upper memory cell group.

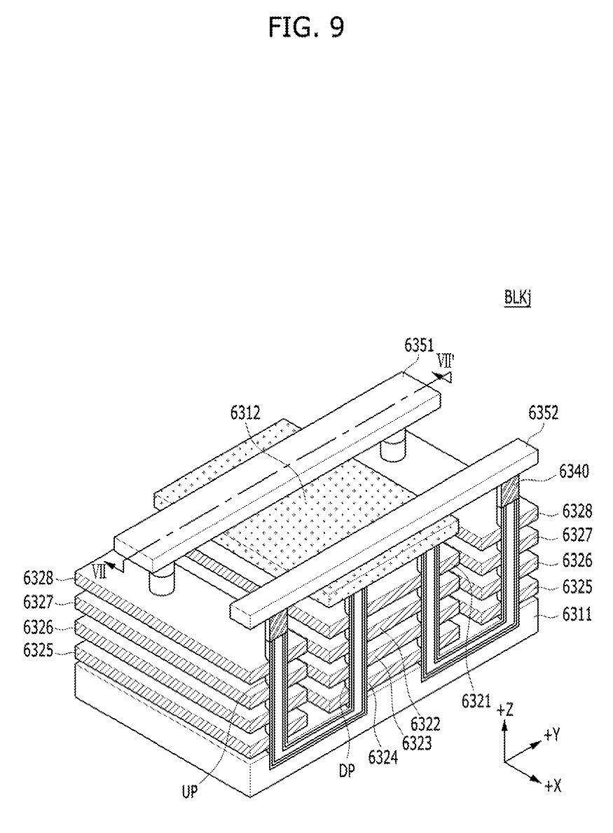

Hereinbelow, detailed descriptions will be made with reference to FIGS. 9 to 11, which show a memory device in a memory system, according to an embodiment implemented with a three-dimensional (3D) nonvolatile memory device different from the first structure.

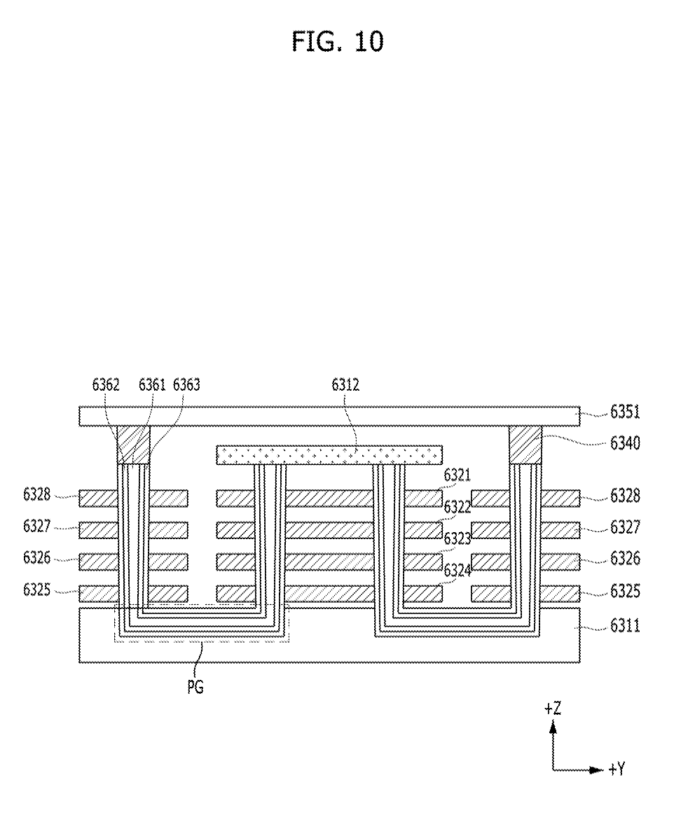

FIG. 9 is a perspective view schematically illustrating the memory device implemented with the three-dimensional (3D) nonvolatile memory device, which is different from the first structure described above with reference to FIGS. 5 to 8, and showing a memory block BLKj of the plurality of memory blocks of FIG. 4. FIG. 10 is a cross-sectional view illustrating the memory block BLKj taken along the line VII-VII′ of FIG. 9.

Referring to FIGS. 9 and 10, the memory block BLKj among the plurality of memory blocks of the memory device 150 of FIG. 1 may include structures extending in the first to third directions.

A substrate 6311 may be provided. For example, the substrate 6311 may include a silicon material doped with a first type impurity. For example, the substrate 6311 may include a silicon material doped with a p-type impurity. The substrate 6311 may be a p-type well, for example, a pocket p-well. The substrate 6311 may further include an n-type well which surrounds the p-type well. Although, in the embodiment of the present invention, the substrate 6311 is exemplified as being the p-type silicon, it is noted that the substrate 6311 is not limited thereto.

First to fourth conductive materials 6321 to 6324 extending in an x-axis direction and a y-axis direction are provided over the substrate 6311. The first to fourth conductive materials 6321 to 6324 may be separated by a preset distance in the z-axis direction.

Fifth to eighth conductive materials 6325 to 6328 extending in the x-axis direction and the y-axis direction may be provided over the substrate 6311. The fifth to eighth conductive materials 6325 to 6328 may be separated by the preset distance in the z-axis direction. The fifth to eighth conductive materials 6325 to 6328 may be separated from the first to fourth conductive materials 6321 to 6324 in the y-axis direction.

A plurality of lower pillars DP passing through the first to fourth conductive materials 6321 to 6324 may be provided. Each lower pillar DP may extend in the z-axis direction. Also, a plurality of upper pillars UP passing through the fifth to eighth conductive materials 6325 to 6328 may be provided. Each upper pillar UP may extend in the z-axis direction.

Each of the lower pillars DP and the upper pillars UP may include an internal material 6361, an intermediate layer 6362, and a surface layer 6363. The intermediate layer 6362 may serve as a channel of the cell transistor. The surface layer 6363 may include a blocking dielectric layer, a charge storing layer and a tunneling dielectric layer.

The lower pillar DP and the upper pillar UP may be electrically coupled with each other through a pipe gate PG. The pipe gate PG may be disposed in the substrate 6311. For example, the pipe gate PG may include the same material as the lower pillar DP and the upper pillar UP.

A doping material 6312 of a second type extending in the x-axis direction and the y-axis direction may be provided over the lower pillars DP. For example, the doping material 6312 of the second type may include an n-type silicon material. The doping material 6312 of the second type may serve as a common source line CSL.

Drains 6340 may be provided over the upper pillars UP. The drains 6340 may include an n-type silicon material. First and second upper conductive materials 6351 and 6352 extending in the y-axis direction may be provided over the drains 6340.

The first and second upper conductive materials 6351 and 6352 may be spaced apart along the x-axis direction. The first and second upper conductive materials 6351 and 6352 may be formed of a metal. The first and second upper conductive materials 6351 and 6352 and the drains 6340 may be electrically coupled with each other through contact plugs. The first and second upper conductive materials 6351 and 6352 respectively serve as first and second bit lines BL1 and BL2.

The first conductive material 6321 may serve as a source select line SSL. The second conductive material 6322 may serve as a first dummy word line DWL1. The third and fourth conductive materials 6323 and 6324 serve as first and second main word lines MWL1 and MWL2, respectively. The fifth and sixth conductive materials 6325 and 6326 serve as third and fourth main word lines MWL3 and MWL4, respectively. The seventh conductive material 6327 may serve as a second dummy word line DWL2. The eighth conductive material 6328 may serve as a drain select line DSL.

The lower pillar DP and the first to fourth conductive materials 6321 to 6324 adjacent to the lower pillar DP form a lower string. The upper pillar UP and the fifth to eighth conductive materials 6325 to 6328 adjacent to the upper pillar UP form an upper string. The lower string and the upper string may be electrically coupled with each other through the pipe gate PG. One end of the lower string may be electrically coupled to the doping material 6312 of the second type which serves as the common source line CSL. One end of the upper string may be electrically coupled to a corresponding bit line through the drain 6340. One lower string and one upper string form one cell string which is electrically coupled between the doping material 6312 serving as the common source line CSL and a corresponding one of the upper conductive material layers 6351 and 6352 serving as the bit line BL.

For example, the lower string may include a source select transistor SST, the first dummy memory cell DMC1, and the first and second main memory cells MMC1 and MMC2. The upper string may include the third and fourth main memory cells MMC3 and MMC4, the second dummy memory cell DMC2, and a drain select transistor DST.

In FIGS. 9 and 10, the upper string and the lower string may form a NAND string NS. The NAND string NS may include a plurality of transistor structures TS. Since the transistor structure included in the NAND string NS in FIGS. 9 and 10 is described above in detail with reference to FIG. 7, a detailed description thereof will be omitted herein.

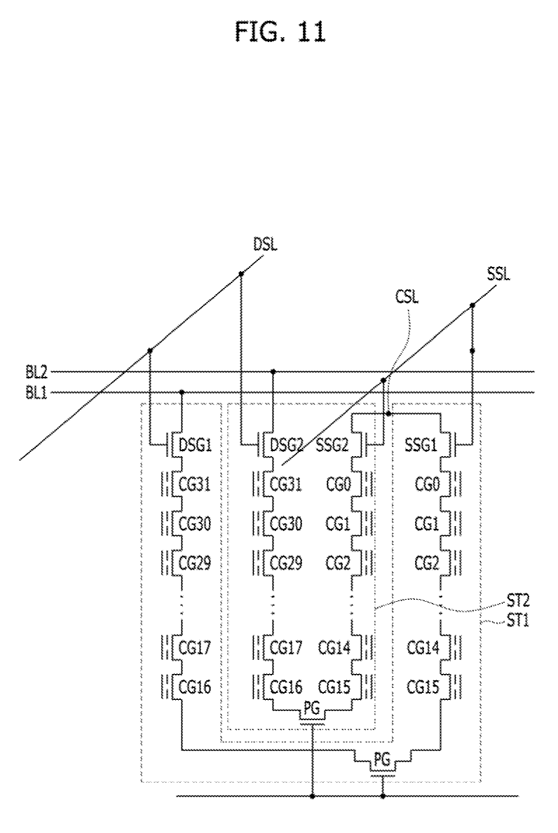

FIG. 11 is a circuit diagram illustrating the equivalent circuit of the memory block BLKj having the second structure as described above with reference to FIGS. 9 and 10. For the sake of convenience, only a first string ST1 and a second string ST2, which form a pair in the memory block BLKj in the second structure are shown.

Referring to FIG. 11, in the memory block BLKj having the second structure among the plurality of blocks of the memory device 150, cell strings, each of which is implemented with one upper string and one lower string electrically coupled through the pipe gate PG as described above with reference to FIGS. 9 and 10, may be provided in such a way as to define a plurality of pairs.

Namely, in the certain memory block BLKj having the second structure, memory cells CG0 to CG31 stacked along a first channel CH1 (not shown), for example, at least one source select gate SSG1 and at least one drain select gate DSG1 may form a first string ST1, and memory cells CG0 to CG31 stacked along a second channel CH2 (not shown), for example, at least one source select gate SSG2 and at least one drain select gate DSG2 may form a second string ST2.

The first and second strings ST1, ST2 may be electrically coupled to the same drain select line DSL and the same source select line SSL. The first string ST1 may be electrically coupled to a first bit line BL1. The second string ST2 may be electrically coupled to a second bit line BL2.

Although FIG. 11 shows that the first string ST1 and the second string ST2 are electrically coupled to the same drain select line DSL and the same source select line SSL, it may be envisaged that the first string ST1 and the second string ST2 may be electrically coupled to the same source select line SSL and the same bit line BL, the first string ST1 may be electrically coupled to a first drain select line DSL1 and the second string ST2 may be electrically coupled to a second drain select line DSL2. Further, it may be envisaged that the first string ST1 and the second string ST2 may be electrically coupled to the same drain select line DSL and the same bit line BL, the first string ST1 may be electrically coupled to a first source select line SSL1 and the second string ST2 may be electrically coupled a second source select line SSL2.

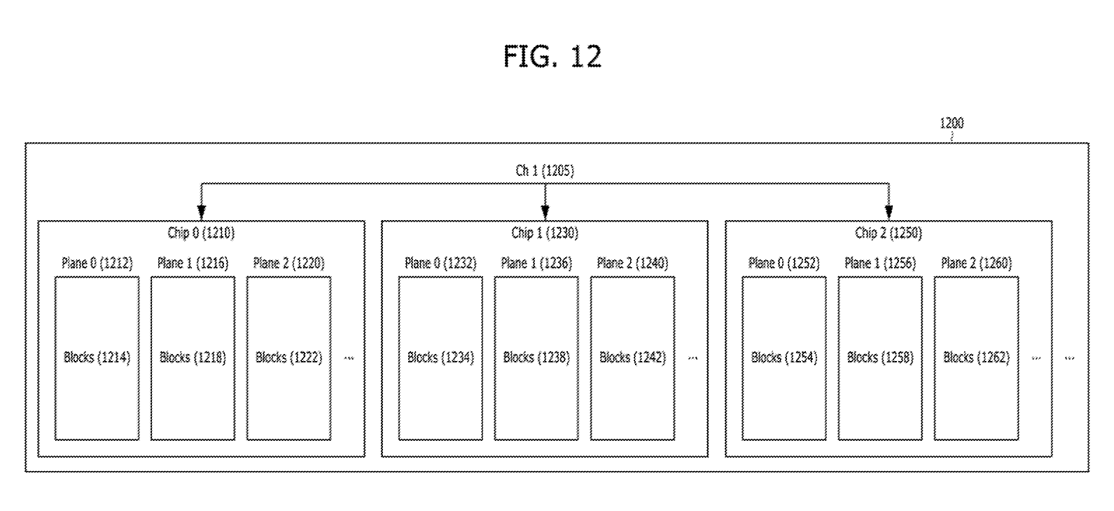

Hereinafter, an operation of processing data to a memory device in a memory system, according to an embodiment of the present invention will be described with reference to FIGS. 12 to 14. In particular, a command operation corresponding to a command received from a host 102, for example, an operation of writing data to the memory device will be described in detail.

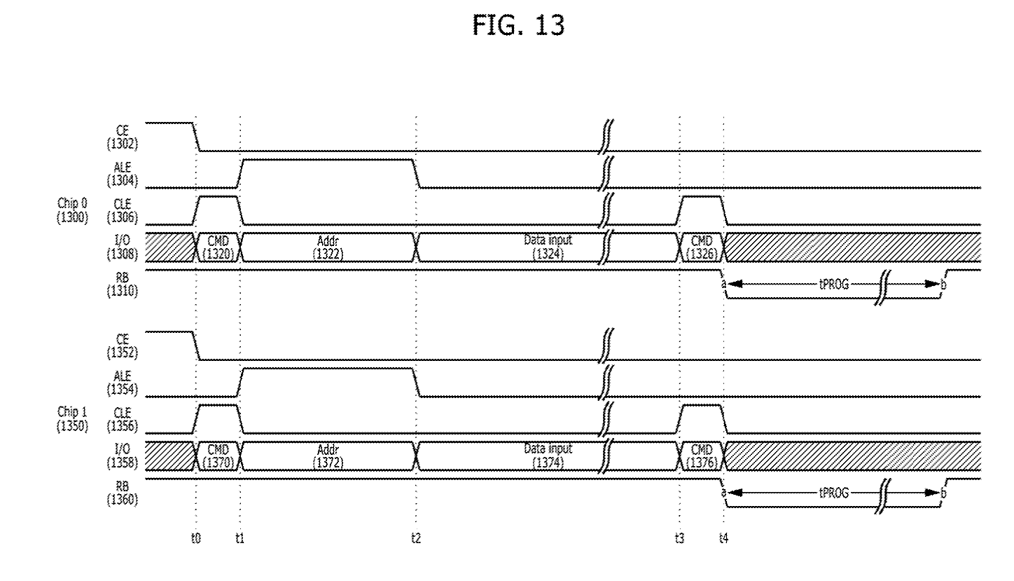

FIGS. 12 and 13 are diagrams for schematically describing an example of an operation of processing data to a memory device in the memory system according to an embodiment of the present invention. Hereinafter, for the sake of convenience of description, a data processing operation in the following case will be taken as an example. During the data processing operation, the memory system 110 illustrated in FIG. 1 may store write data corresponding to a write command received from the host 102 into a buffer/cache included in the memory 144 of the controller 130, and write the data stored in the buffer/cache into a plurality of memory blocks included in the memory device 150. The memory system 110 may back up or copy the data written into the plurality of memory blocks to another plurality of memory blocks included in the memory device 150 or write the same pattern of data as the data written in the plurality of memory blocks into another plurality of memory blocks included the memory device 150.

In the present embodiment, the memory device 150 may include a plurality of memory chips, each of which may include a plurality of planes each having a plurality of memory blocks. Furthermore, write data corresponding to a write command received from the host 102 may be programmed and stored into the plurality of memory blocks. In particular each of the memory blocks may include a plurality of pages. The write data may be programmed and stored in the pages of the corresponding memory block.

When the write data are programmed and stored into memory blocks included in planes of an arbitrary memory chip included in the memory device 150 and the write data or the same pattern of data as the write data are programmed and stored into memory blocks included in planes of another arbitrary memory chip, for example, when backup data of write data programmed to an arbitrary memory chip are programmed to another arbitrary memory chip or the same specific pattern of data are programmed to a plurality of memory chips, the memory system may perform an operation of processing data among the plurality of memory chips included in the memory device 150, such that the write data and the backup data or the same specific pattern of data are programmed to a plurality of memory chips at the same time, the plurality of memory chips being coupled to the same channel and sharing a data bus. The plurality of memory chips sharing the data bus may be enabled at the same time before the write data are programmed. Then, when the write data are transmitted to the memory chips through the shared data bus of the memory chips, the write data and the backup data or the same specific pattern of write data may be programmed at the same time.

Hereinafter, for the sake of convenience of description, the configuration in which a data processing operation in the memory system is performed by the controller 130 will be taken as an example.

As described above, however, the processor 134 included in the controller 130 may perform a data processing operation through FTL, for example.

In the present embodiment, the controller 130 may store write data corresponding to a write command received from the host 102 into a buffer included in the memory 144 of the controller 130, and then program the data stored in the buffer to multi-memory chips. That is, the controller 130 may program the data to a plurality of pages of a memory block included in a plane of an arbitrary memory chip selected from a plurality of memory chips included in the memory device 150. For example, the controller 130 may program the data to a memory block included in a first plane of a first memory chip, and program backup data of the programmed data to a plurality of pages of a memory block included in a plane of another arbitrary memory chip. For example, the controller 130 may program the backup data to a memory block included in a first plane of a second memory chip which shares a data bus with the first memory chip. Furthermore, the controller 130 may program the same specific pattern of data to multi-memory chips. That is, the controller 130 may program the same specific pattern of data to a plurality of pages of a memory block included in a plane of an arbitrary memory chip selected from the plurality of memory chips included in the memory device 150. For example, the controller 130 may program the same specific pattern of data to a memory block included in the first plane of the first memory chip. Furthermore, the controller 130 may program the same specific pattern of data to a plurality of pages of a memory block included in a plane of another arbitrary memory chip. For example, the controller 130 may program the same specific pattern of data to a memory block included in the first plane of the second memory chip which shares the data bus with the first memory chip.

In the present embodiment, when the data stored in the buffer and the backup data are programmed to a plurality of memory chips or multi-memory chips or the same specific pattern of data are programmed to a plurality of memory chips or multi-memory chips, the controller 130 may enable memory chips which are coupled to the same channel and share a data bus, and then transmit write data into the enabled memory chips through the shared data bus of the enabled memory chips, such that the write data, for example, the data stored in the buffer and the backup data or the same specific pattern of data are programmed to the enabled memory chips at the same time. Thus, the program time for the plurality of memory chips can be minimized. In other words, the time required for transmitting a program command to the memory chips, enabling the memory chips, and transmitting the write data can be minimized to reduce the program overhead of the memory device 150. As a result, the program performance of the memory device 150 can be maximized. Now, referring to FIGS. 12 and 13, the data processing operation in the plurality of memory chips included in the memory device 150 will be described in more detail.

First, referring to FIG. 12, the controller 130 may store write data corresponding to a write command received from the host 102 in a buffer included in the memory 144 of the controller 130, and then program (or write) and store the write data stored in the buffer into pages of memory blocks included in planes of memory chips included in a memory device 1200, for example, chip 0(1210), chip 1(1230), and chip 2(1250).

As described above, the memory device 1200 may include the plurality of memory chips, for example, the chip 0(1210), the chip 1(1230), and the chip 2(1250). Each of the memory chips may include a plurality of planes. For example, the chips 0(1210), 1(1230), and 2(1250) may include planes 0(1212, 1232, and 1252), 1(1216, 1236, and 1256), and 2(1220, 1240, and 1260), respectively. The planes may include a plurality of memory blocks 1214, 1218, and 1222, 1234, 1238, and 1242, and 1254, 1258, and 1262, respectively.

Hereinafter, the following case will be taken as an example for description. The chips 0(1210), 1(1230), and 2(1250) may be coupled to the same channel, for example, channel 1(1205), and share a data bus. Furthermore, write data corresponding to a write command received from the host 102 may be programmed to the chips 0(1210), 1(1230), and 2(1250) coupled to the channel 1(1205) and share a data bus.

More specifically, the controller 130 may store the write data corresponding to the write command received from the host 102 into a buffer included in the memory 144 of the controller 130, and then check the write data stored in the buffer. At this time, the controller 130 may check the information type of the write data, and determine whether the write data are data to be programmed to the plurality of memory chips included in the memory device 1200, based on their information type. For example, the controller 130 may check the write data and the information type of the write data, and determine whether the write data are data to be programmed to multi-memory chips among the plurality of memory chips of the memory device 1200. For example, the controller 130 may check whether the write data are data which are not only programmed to an arbitrary memory chip selected from the plurality of memory chips of the memory device 1200, for example, the chip 0(1210), but also programmed to other arbitrary memory chips, for example, the chip 1(1230) and the chip 2(1250).

The controller 130 may check whether the write data and backup data of the write data are programmed to the plurality of memory chips, based on the information type of the write data. For example, the controller 130 may check whether the write data are programmed to pages of the memory block 1214 included in the plane 0(1212) of the chip 0(1210) and the backup data of the write data are programmed to pages of the memory block 1234 included in the plane 0(1232) of the chip 1(1230) or pages of the memory block 1254 included in the plane 0(1252) of the chip 2(1250). The backup data may include the LSB (Least Significant Bit) page data programmed to the LSB page among the pages of the memory block 1214 included in the plane 0(12.12) of the chip 0(1210). For example, the controller 130 may program the write data to the pages of the memory block 1214 included in the plane 0(1212) of the chip 0(1210), and program the backup data of the write data, for example, the LSB page data to the pages of the memory block 1234 included in the plane 0(1232) of the chip 1(1230) or the pages of the memory block 1254 included in the plane 0(1252) of the chip 2(1250). Thus, the controller 130 may back up the write data into the chip 1(1230) and the chip 2(1250) as well as the chip 0(1210) having the write data programmed therein.

Furthermore, the controller 130 may check whether the same data or the same pattern of data are programmed to a plurality of memory chips, based on the information type of the write data. For example, the controller 130 may check whether the same pattern of write data are programmed to the pages of the memory block 1234 included in the plane 0(1232) of the chip 1(1230) or the pages of the memory block 1254 included in the plane 0(1252) of the chip 2(1250) as well as the pages of the memory block 1214 included in the plane 0(1212) of the chip 0(1210). At this time, when data ‘0xFF’ is written as the MSB (Most Significant Bit) page data programmed to the MSB page, among the pages of the memory blocks 1214, 1234, and 1254 included in the planes 0(1212, 1232, and 1252) of the chips 1210, 1230, and 1250, the same pattern of write data may correspond to data having the same MSB page data. For example, the controller 130 may program the write data to the pages of the memory block 1214 included in the plane 0(1212) of the chip 0(1210), and program the same data or the same pattern of data as the write data, for example, data having the same MSB page data to the pages of the memory block 1234 included in the plane 0(1232) of the chip 1(1230) or the pages of the memory block 1254 included in the plane 0(1252) of the chip 2(1250). Thus, the controller 130 may program the same data or the same pattern of data as the write data to the chip 1(1230) and the chip 2(1250) as well as the chip 0(1210) having the write data programmed therein.

The controller 130 may check the write data stored in the buffer or the information type of the write data, and check whether the write data are programmed to multi-memory chips among the plurality of memory chips of the memory device 1200. For example the controller 130 may check whether the write data are data to be programmed to the multi-memory chips among the plurality of memory chips of the memory device 1200. For example, the controller 130 may check whether the write data and the backup data of the write data are data to be programmed to the multi-memory chips or whether the same write data or the same pattern of write data are data to be programmed to the multi-memory chips.

Furthermore, for programming write data stored in the buffer to the multi-memory chips of the memory device 1200, the controller 130 may transmit a chip enable signal to the multi-memory chips to enable the multi-memory chips, and then program the write data to the multi-memory chips. At this time, the multi-memory chips of the memory device 1200, for example, chips 0(1210), 1(1230), and 3(1250) may be coupled to the channel 1(1205) and share a data bus. The controller 130 may transmit the chip enable signal to the multi-memory chips through the channel 1(1205) to enable the multi-memory chips 0(1210), the chip 1(1230), and the chip 3(1250) at the same time.

When data are programmed to the memory chips of the memory device 1200, the controller 130 may generate a descriptor for the data programmed to the respective memory chips of the memory device 1200, and transmit a command containing the descriptor to the respective memory chips to program the data to the memory chips. At this time, since the write data stored in the buffer, that is, the write data and the backup data or the same data or the same pattern of data are programmed to the multi-memory chips of the memory device 1200, the controller 130 may generate only one descriptor for the data programmed to the multi-memory chips, and then transmit a command containing the descriptor to the multi-memory chips to program the data to the multi-memory chips. For example, when the same write data are programmed to the multi-memory chips of the memory device 1200, the controller 130 may generate one descriptor for the data programmed to the multi-memory chips, and then transmit a command containing the descriptor to the multi-memory chips to program the data to the multi-memory chips of the memory device 1200.

The controller 130 may transmit the write data stored in the buffer to the multi-memory chips through the shared data bus coupled to the channel 1(1205), and program the write data to the enabled multi-memory chips, for example chips 0(1210), 1(1230), and 3(1250) at the same time. For example, the controller 130 may program the write data to the pages of the memory block 1214 included in the plane 0(1212) of the chip 0(1210), and program the backup data of the write data to the pages of the memory block 1234 included in the plane 0(1232) of the chip 1(1230) or the pages of the memory block 1254 included in the plane 0(1252) of the chip 2(1250). Furthermore, the controller 130 may program the same pattern of write data to the pages of the memory block 1234 included in the plane 0(1232) of the chip 1(1230) or the pages of the memory block 1254 included in the plane 0(1252) of the chip 2(1250) as well as the pages of the memory block 1214 included in the plane 0(1212) of the chip 0(1210).

Hereinafter, referring to FIG. 13, enable and program operations of multi-memory chips of the memory device 1200, for example, chips 0(1210) and chip 1(1230) coupled to the channel 1(1205) will be described in more detail.

Referring to FIG. 13, when write data corresponding to a write command received from the host 102 are programmed to multi-memory chips as arbitrary memory chips which are coupled to the same channel and share a data bus, selected from the plurality of memory chips included in the memory device 150, for example, chips 0(1300) and chip 1(1350), the controller 130 may transmit chip enable (CE) signals 1302 and 1352 to the chip 0(1300) and the chip 1(1350) to enable the chip 0(1300) and the chip 1(1350), at a time point t0. For example, the write data may be programmed to the chip 0(1300) and backup data of the write data may be programmed to the chip 1(1350) or the same data or the same pattern of write data may be programmed to the chip 0(1300) and the chip 1(1350),

Then, the controller 130 may transmit command latch enable (CLE) signals 1306 and 1356 during a time period from t0 to t1. As described above, the controller 130 may generate one descriptor for the data programmed to the chips 0(1300) and 1(1350), and then transmit commands 1320 and 1370 containing the descriptor as input/output (I/O) signals 1308 and 1358 of chips 0(1300) and 1(1350) to chips 0(1300) and 1(1350).

Furthermore, during a time period from t1 to t2, the controller 130 may transmit address latch enable signals 1304 and 1354, and transmit addresses 1322 and 1372 for the write data transmitted to the shared data bus of the chips 0(1300) and 1(1350) as their I/O signals 1308 and 1358 to chips 0(1300) and 1(1350).

At this time, when write data corresponding to a write command received from the host 102 are programmed to different planes or different memory blocks of the chip 0(1300) among the plurality of planes included in the chip 0(1300) or the plurality of blocks included in the plurality of planes, for example, when the write data and the backup data or the same write data or the same pattern of write data are programmed to the first and second planes of the chip 0(1300) or the first and second memory blocks of the first plane of the chip 0(1300), the controller 130 may transmit an address for the first plane or the first memory block of the chip 0(1300) as the I/O signal 1308 of the chip 0(1300) during a time period from t1 to t2, and then transmit an address for the second plane or the second memory block of the chip 0(1300) as the I/O signal 1308 of the chip 0(1300) at the time point t2.

Furthermore, during a time period from t2 to t3, the controller 130 may transmit write data 1324 and 1374 as the I/O signals 1308 and 1358 of the chips 0(1300) and 1(1350) to the chips 0(1300) and 1(1350) through a shared data bus thereof coupled to the same channel. That is, according to the addresses 1322 and 1372 for the write data transmitted as the I/O signals 1308 and 1358 of chips 0(1300) and 1(1350) during the time period from t1 to t2, the controller 130 may transmit the write data 1324 and 1374 as their I/O signals 1308 and 1358 to the chips 0(1300) and 1(1350) through their shared data bus during the time period from t2 to t3. Thus, the write data 1324 and 1374 transmitted through the shared data bus may be programmed to the chips 0(1300) and chip 1(1350).

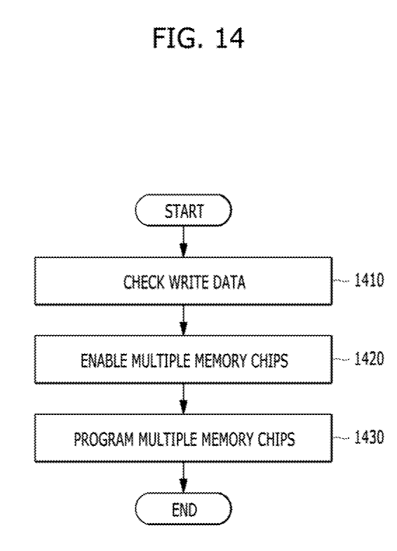

As described above, the controller 130 may transmit the chip enable signals 1302 and 1352 and the data programmed to the multi-memory chips, for example, the commands 1320 and 1370 containing one descriptor for the write data, the addresses 1322 and 1372 for the write data, and the write data 1324 and 1374 to the chips 0(1300) and 1(1350), that is, the multi-memory chips through the shared data bus of the chip 0(1300) and the chip 1(1350) coupled to the same channel at the same time. Thus, the multi-memory chips of the memory device 1200, which are coupled to the same channel and share the data bus, may receive the write data, for example, the write data and the backup data or the same write data or the same pattern of write data at the same time, and the write data may be programmed to the multi-memory chips through the one shared data bus at the same time, instead of data buses corresponding to the respective multi-memory chips. Now, referring to FIG. 14, an operation of processing data in the memory system according to an embodiment of the present invention will be described in more detail.

Referring now to FIG. 14, when a write command is received from the host, the memory system may check write data corresponding to the write command, or check whether the write data are programmed to multi-memory chips among the plurality of memory chips, at step S1410.

At step S1420, when the write data corresponding to the write command are programmed to multi-memory chips, the memory system may enable the multi-memory chips through a shared data bus so that the write data are programmed to the multi-memory chips coupled to the same channel and share the data bus, for example, the write data and backup data of the write data or the same write data or the same pattern of write data are programmed to the multi-memory chips.

Then, at step S1430, the memory system may transmit the write data to the multi-memory chips through the shared data bus such that the write data are programmed to the multi-memory chips at the same time. For example, the write data and the backup data of the write data or the same write data or the same pattern of write data may be programmed to the multi-memory chips at the same time.

The write operation for the write data corresponding to the write command received from the host, or particularly the operation of programming the write data to the multi-memory chips among the plurality of memory chips of the memory device, that is, the data processing operation according to the embodiment of the present invention has been described in detail with reference to FIGS. 12 and 13. Thus, the detailed descriptions thereof are omitted herein.

According to an embodiment of the present invention, the memory system and the operating method thereof can minimize the complexity and performance reduction thereof, thereby rapidly and stably processing data to a memory device.

Although various embodiments have been described for illustrative purposes, it will be apparent to those skilled in the art that various changes and modifications may be made without departing from the spirit and scope of the invention as defined in the following claims.

What is claimed is:

1. A memory system comprising:
a memory device comprising:
a plurality of memory chips each memory chip comprising a plurality of planes, each plane comprising a plurality of memory blocks, each block comprising a plurality of pages;
the plurality of pages being suitable for storing read data and write data requested from a host, each page comprising a plurality of memory cells coupled to a plurality of word lines; and
to a controller suitable for checking the write data corresponding to a command received from the host, programming the write data to pages of memory blocks included in planes of a first memory chip, and programming first data for the write data to pages of memory blocks included in planes of a second memory chip.

2. The memory system of claim 1, wherein the first data comprise backup data of the write data.

3. The memory system of claim 1, wherein the first data comprise data programmed to the LSB (Least Significant Bit) page among the pages of the memory blocks included in the planes of the first memory chip.

4. The memory system of claim 1, wherein the first data have the same pattern as the write data.

5. The memory system of claim 1, wherein the first data comprise the same data as data programmed to the MSB (Most Significant Bit) page among the pages of the memory blocks included in the planes of the first memory chip and data programmed to the MSB page among the pages of the memory blocks included in the planes of the second memory chip.

6. The memory system of claim 1, wherein the first and second memory chips are coupled to the same channel and share a data bus.

7. The memory system of claim 6, wherein the controller enables the first and second memory chips through the shared data bus of the first and second memory chips, and transmits the write data to the first and second memory chips through the shared data bus at the same time.

8. The memory system of claim 7, wherein the controller generates one descriptor for the data programmed to the first and second memory chips, and then transmits a command containing the descriptor to the first and second memory chips through the shared data bus at the same time.

9. The memory system of claim 1, wherein the controller checks the write data and information type of the write data and programs the write data to multi-memory chips among the memory chips at the same time.

10. The memory system of claim 1, wherein the controller programs the write data to pages of a first memory block included in a first plane of the first memory chip, and then programs the first data to pages of a memory block included in a second plane of the first memory chip or pages of a second memory block included in the first plane.

11. An operating method of a memory system, comprising:
checking write data corresponding to a command received from a host, for a plurality of pages included in each of a plurality of memory blocks of a memory device and each including a plurality of memory cells coupled to a plurality of word lines;
enabling first and second memory chips among a plurality of memory chips included in the memory device; and
programming the write data to pages of memory blocks included in planes of the first memory chip, and programming first data for the write data to pages of memory blocks included in planes of the second memory chip.

12. The operating method of claim 11, wherein the first data comprise backup data of the write data.

13. The operating method of claim 11, wherein the first data comprise data programmed to the LSB page among the pages of the memory blocks included in the planes of the first memory chip.

14. The operating method of claim 11, wherein the first data have the same pattern as the write data.

15. The operating method of claim 11, wherein the first data comprise the same data as data programmed to the MSB page among the pages of the memory blocks included in the planes of the first memory chip and data programmed to the MSB page among the pages of the memory blocks included in the planes of the second memory chip.

16. The operating method of claim 11, wherein the first and second memory chips are coupled to the same channel and share a data bus.

17. The operating method of claim 16, wherein the enabling of the first and second memory chips comprises enabling the first and second memory chips through the shared data bus of the first and second memory chips, and
the programming of the write data comprises transmitting the write data to the first and second memory chips through the shared data bus at the same time.

18. The operating method of claim 17, wherein the transmitting of the write data comprises:
generating one descriptor for the data programmed to the first and second memory chips; and
transmitting a command containing the descriptor to the first and second memory chips through the shared data bus at the same time.

19. The operating method of claim 11, wherein the checking of the write data comprises checking the write data and information type of the write data, and checking whether the write data are programmed to multi-memory chips among the memory chips at the same time.

20. The operating method of claim 11, wherein the programming of the write data comprises programming the write data to pages of a first memory block included in a first plane of the first memory chip, and then programming the first data to pages of a memory block included in a second plane of the first memory chip or pages of a second memory block included in the first plane.
